(19) United States
(12) Patent Application Publication
(10) Pub. No.: US 2013/0265069 A1
(43) Pub. Date: Oct. 10, 2013

(54) Liquid Crystal Panel, Liquid Crystal Module, and Method Of Determining Reason Behind Bad Display

(71) Applicants: Mingfeng Deng, Shenzhen (CN); Jungmao Tsai, Shenzhen (CN); Shiue-shih Liao, Shenzhen (CN); Yizhuang Zhuang, Shenzhen (CN); Songxian Wen, Shenzhen (CN)

(72) Inventors: Mingfeng Deng, Shenzhen (CN); Jungmao Tsai, Shenzhen (CN); Shiue-shih Liao, Shenzhen (CN); Yizhuang Zhuang, Shenzhen (CN); Songxian Wen, Shenzhen (CN)

(73) Assignee: SHENZHEN CHINA STAR OPTOELECTRONICS TECHNOLOGY CO. LTD., Shenzhen (CN)

(21) Appl. No.: 13/512,885

(22) PCT Filed: Apr. 16, 2012
(86) PCT No.: PCT/CN12/74082

§ 371 Date: May 30, 2012

(30) Foreign Application Priority Data
Apr. 10, 2012 (CN) 201210103302.2

(51) Int. Cl. G01R 31/3187

(52) U.S. Cl. 324/750.3

(57) ABSTRACT

The present invention discloses a liquid crystal panel, which, in shorting bar area, connects scan signal line to scan signal test point through a first switch, connects data signal line to data signal test point through a first unidirectional circuit or a second switch, and connects common electrode to common electrode test point through conductive wire. The present invention also discloses a liquid crystal module and a method of determining reason behind bad display for liquid crystal module. With the method, the liquid crystal panel of the present invention can realize to spare the cutting of test leads of shorting bar area and cutting facility used in cell process.

### BACKGROUND OF THE INVENTION

1. Field of the Invention

The present invention relates to the field of liquid crystal displaying techniques, and in particular to a liquid crystal panel, liquid crystal module and method of determining reason behind bad display.

2. The Related Arts

Due to the advantages of low radiation, low power consumption, and light weight, more and more electronic devices adopt liquid crystal display for display panel, such as, mobile phone, computers and TV; where Thin Film Transistor (TFT) liquid crystal display device is one type of the liquid crystal display device.

The operating theory behind TFT liquid crystal display device is: by imposing an appropriate voltage on the liquid crystal layer sandwiched between array glass substrate and color filter glass substrate so that the liquid crystal molecules in the liquid crystal layer will be deflected under the effect of voltage; by varying the voltage, different penetration rate can be obtained to realize the liquid crystal display.

The manufacture process of FTF liquid crystal display device can be divided into array process, cell process and module process. The array process is similar to the semiconductor process, with the difference of fabricating TFT on the glass to obtain the TFT glass substrate. The cell process is to combine the TFT glass substrate from the array process with a color filter (CF) glass substrate and injects liquid crystal between the two substrates, and then cuts the large glass into a plurality of panels. The module process is to assemble the panel obtained from the cell process with other elements, such as, backlight panel, circuit board, and so on, to form a module.

In the cell process, the panels must undergo display inspection. The inspection technique is often by using shorting bar panel layout, as shown in FIG. 1. In FIG. 1, by shorting all the R, G, B data electrodes in panel pixel area 10 with shorting bar on the peripheral to form test point 1, test point 2 and test point 3, and shorting odd line 20 and even line 21 of all the scan lines with shorting bar to form test point 4 and test point 5. Test point 6 is a common electrode. For testing display, shorting bar test facility sends test signal to corresponding test points 1, 2, 3, 4, 5, 6 to light the product for fault inspection. After completing the display test of the cell process, the shorting bars on the normal products will be cut off by a laser facility, as shown in FIG. 1, dash line 7 indicates the laser cutting the test leads connecting to test points 1, 2, 3, 4, 5, 6. Then, the after-cut product undergoes the polarizer attachment to form a panel, and then undergoes the next module process.

In module process, chip on film (COF) attachment and circuit board assembly are performed on the panel, and the module process display inspection is performed. When the product is tested to show bad display, it is necessary to determine whether the bad reason is in the cell process or the module process. However, because the test leads of shorting bars are all cut after the test in the cell process, the shorting bars in the cell process can no longer be used for display test. As a result, the bad reason is difficult be attributed to either cell process or module process, and the product quality is affected. On the other hand, because the test leads of shorting bars are all cut after the test in the cell process, the shorting bars cannot be used for display test for cell process in subsequent quality assurance. Thus, the product quality cannot be assured.

### SUMMARY OF THE INVENTION

The technical issue to be addressed by the present invention is to provide a liquid crystal module, liquid crystal panel and method of determining reason behind bad display, able to continue using the test leads in the shorting bar area to perform subsequent display test on liquid crystal panel after cell process to achieve the object of determining the reason of bad display being whether in cell process or in module process and resulting in the improvement of bad display.

The present invention provides a liquid crystal panel, which comprises: a pixel area and a shorting bar area for testing, disposed in the peripheral area of the pixel area. The pixel area of the liquid crystal panel is disposed with a plurality of data signal lines, a plurality of scan signal lines and common electrodes. The shorting bar area further comprises a first area and a second area. The first area is disposed with a plurality of first switches, a plurality of scan signal test points and common electrode test point; and the second area is disposed with a plurality of data signal test points, and a plurality of unidirectional circuit or second switches. Each of the data signal lines is connected with data signal test point through a first unidirectional circuit or second switch. The first unidirectional circuit is a diode, with anode as the input terminal to connect with data signal test point, and cathode as the output terminal to connect with data signal line. Each of the scan signal lines is connected with scan signal test point through a first switch. The common electrodes comprise the common electrode of color film glass substrate and common electrode of array glass substrate. The common electrode of color film glass substrate and common electrode of array glass substrate are connected to common electrode test point of the first area through conductive wire.

According to a preferred embodiment of the present invention, the first area further comprises: control signal input point for inputting control signal to the first switches. The first switch is a thin film transistor (TFT), having a source terminal, a drain terminal and a gate terminal, with source terminal connected to scan signal line, drain terminal connected to scan signal test point and gate terminal connected to control signal input point for inputting control signal to the first switches.

According to a preferred embodiment of the present invention, the second area further comprises: control signal input point for inputting control signal to the second switches. The second switch comprises a first terminal, a second terminal and a control terminal, with first terminal connected to data signal test point, second terminal connected to data signal line and control terminal connected to control signal input point for inputting control signal to the second switches to stay conductive only during product test and off otherwise.

The present invention provides a liquid crystal module, which comprises: a liquid crystal panel, a rigid circuit board and a flex circuit board. The liquid crystal panel further comprises: a pixel area and a shorting bar area for testing, disposed in the peripheral area of the pixel area. The pixel area of the liquid crystal panel is disposed with a plurality of data signal lines, a plurality of scan signal lines and common electrodes. The shorting bar area further comprises a first area and a second area. The first area is disposed with a first switches, a plurality of first scan signal test points and a first common electrode test point; and the second area is disposed with a plurality of first data signal test points, and a plurality of unidirectional circuit or second switches. Each of the data signal lines is connected with first data signal test point through a first unidirectional circuit or second switch. The input terminal of the first unidirectional circuit is connected to first data signal test point, and the output terminal of the first unidirectional circuit is connected to data signal line. Each of the scan signal lines is connected with first scan signal test point through a first switch. The common electrodes are connected to common the first electrode test point of the first area through conductive wire. The rigid circuit board is disposed with a plurality of second scan signal test points, each corresponding to each of a plurality of first scan signal test points respectively. The first data signal test point and the second data signal test point are connected through flex circuit board. The rigid circuit board is disposed with a second common electrode test point, corresponding to the first common electrode test point. The first common electrode test point and the second common electrode test point are connected through flex circuit board. The rigid circuit board is further disposed with a low voltage differential signaling interface, for inputting drive signal of liquid crystal panel.

According to a preferred embodiment of the present invention, the first area further comprises: first control signal input point for inputting control signal to the first switches. The rigid circuit board is disposed with a second control signal input point, corresponding to the first control signal input point for inputting control signal to the first switches. The first control signal input point and the second control signal input point are connected through flex circuit board.

According to a preferred embodiment of the present invention, the first switch is a thin film transistor (TFT), having a source terminal, a drain terminal and a gate terminal, with source terminal connected to scan signal line, drain terminal connected to first scan signal test point and gate terminal connected to first control signal input point for inputting control signal to the first switches.

According to a preferred embodiment of the present invention, the first unidirectional circuit is a diode, with anode to connect with first data signal test point, and cathode to connect with data signal line.

According to a preferred embodiment of the present invention, the second area further comprises: third control signal input point for inputting control signal to the second switches.

According to a preferred embodiment of the present invention, the rigid circuit board is disposed with a fourth control signal input point, corresponding to the third control signal input point for inputting control signal to the second switches. The third control signal input point and the fourth control signal input point are connected through flex circuit board.

According to a preferred embodiment of the present invention, the second switch further comprises: a first terminal, a second terminal and a control terminal, with first terminal connected to first data signal test point, second terminal connected to data signal line and control terminal connected to third control signal input point for inputting control signal to the second switches to stay conductive only during product test and off otherwise.

According to a preferred embodiment of the present invention, the common electrodes comprise the common electrode of color film glass substrate and common electrode of array glass substrate. The common electrode of color film glass substrate and common electrode of array glass substrate are connected to the first common electrode test point of the first area through conductive wire.

The present invention provides a method of determining reasons for bad display of liquid crystal modules, applicable to any liquid crystal module as described above. The method comprises: inputting a first test signal required by the liquid crystal panel to a low voltage differential signaling interface on rigid circuit board for the first test signal to enter the liquid crystal panel through the first path to drive the liquid crystal panel to display; when the liquid crystal panel showing bad display, terminating inputting the first test signal required by the liquid crystal panel to a low voltage differential signaling interface; after terminating inputting the first test signal, making a second test signal entering the liquid crystal panel through second path to drive liquid crystal panel to display, the second path being formed by electrically connecting the second test point on rigid circuit board, through flex circuit board and the first test point on the liquid crystal panel; the second test point further comprising: a second scan signal test point, a second control signal input point, a second common electrode test point and a second data signal test point; the first test point further comprising: a first scan signal test point, a first control signal input point, a first common electrode test point and a first data signal test point; determining whether the liquid crystal panel showing bad display after second test signal inputted, and when the liquid crystal panel showing bad display, the bad reason behind bad display of liquid crystal panel being determined to be in the cell process; otherwise, the bad reason behind bad display of liquid crystal panel being determined to be in the module process.

According to a preferred embodiment of the present invention, the step of making the second test signal entering the liquid crystal panel through the second path further comprising: inputting common electrode reference voltage to the second common electrode test point on rigid circuit board; after inputting common electrode reference voltage, inputting a control signal to the second control signal input point on rigid circuit board to make the first switch of the liquid crystal panel become conductive, wherein the first switch is a thin film transistor (TFT), having a source terminal, a drain terminal and a gate terminal, with source terminal connected to scan signal line, drain terminal connected to first scan signal test point and gate terminal connected to first control signal input point for inputting control signal to the first switches; after inputting control signal, inputting a scan signal to the second scan signal test point on rigid circuit board to make the scan signal to pass the first switch to reach the scan data line; after inputting the scan signal, inputting a data signal to the second data signal input point on rigid circuit board to make the data signal to pass the first unidirectional circuit or the second switch to reach data signal line so as to drive the liquid crystal panel to display; wherein the first unidirectional circuit is a diode, with anode connected to the first data signal test point and cathode connected to data signal line; the second switch having a first terminal, a second terminal and a control terminal, with the first terminal connected to the first data signal test point, the second terminal connected to the data signal line and the control terminal connected to the second control signal input point to the second switch.

According to a preferred embodiment of the present invention, the step of inputting control signal to the second control single input point on rigid circuit board further comprises: inputting a high voltage to the second control single input point on rigid circuit board so as to make the first switch of the liquid crystal panel to become conductive.

The efficacy of the present invention is that to be distinguished from the state of the art. The liquid crystal module of the present invention electrically connects the data signal test point, scan signal test point and common electrode test point on the shorting bar area of the liquid crystal panel to the corresponding data signal test point, the scan signal test point and common electrode test point on the rigid circuit board through the flex circuit board so that when inspecting display, the test leads at the shorting bars area can be used to perform test on the liquid crystal panel. In this manner, when the liquid crystal panel shows bad display, the bad reason can be determined to be attributed to the cell process or the module process to improve the bad display. Also, in the liquid crystal panel of the present invention, the first area of the shorting bar area for testing comprises a plurality of first switches, a plurality of scan signal test points and common electrode test points; the second area comprises a plurality of first unidirectional circuits or the second switches and a plurality of data signal test points; the data signal lines are connected to corresponding data signal test points through the first unidirectional circuit or the second switch, the scan signal lines are connected to corresponding scan signal test points through the first switches. With the above circuitry structure, each of the data signal lines and each of the scan signal lines will not interfere with each other, so that the cell process can spare the cutting of test leads in the shorting bar area and the cutting facility. In this manner, the test leads of the shorting bar area can be used in subsequent fabrication process for performing display on liquid crystal display, resulting in improving the display inspection accuracy and reducing cell process cost.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of a known liquid crystal panel;

FIG. 2 is a schematic view of an embodiment of a liquid crystal panel of the present invention;

FIG. 3 is a schematic view of an embodiment of a liquid crystal module of the present invention;

FIG. 4 is a flowchart of the method of determining reason of bad display of liquid crystal module according to the present invention; and

FIG. 5 is a flowchart of the step of making the second test signal to enter the liquid crystal panel through the second path in FIG. 4.

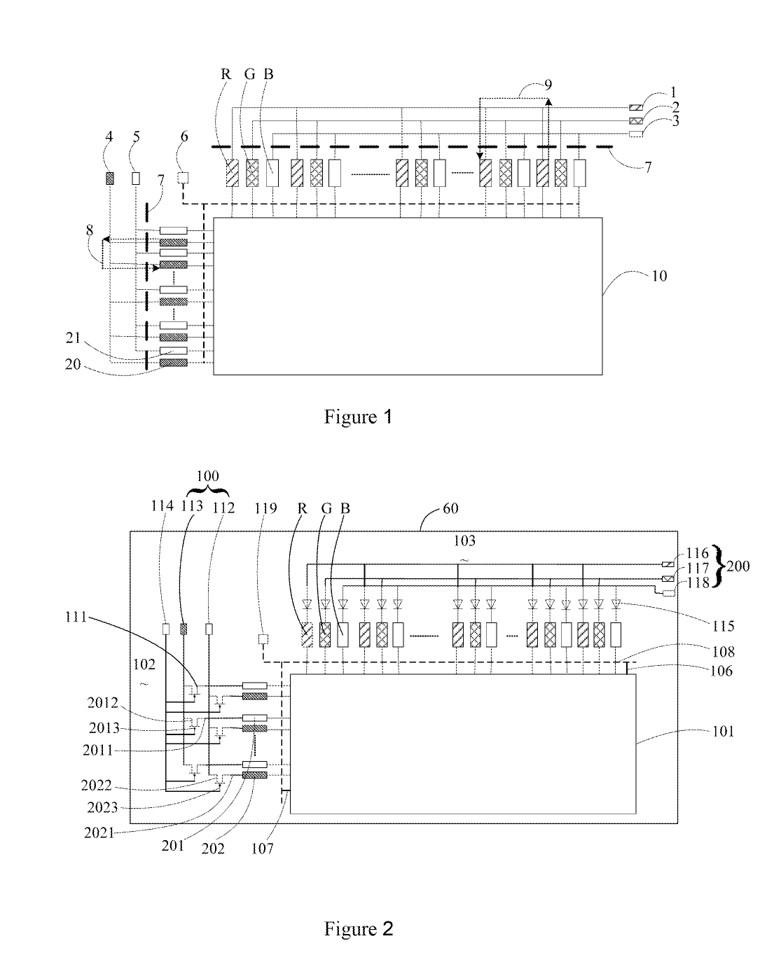

### DETAILED DESCRIPTION OF THE PREFERRED EMBODIMENTS

The following detailed description refers to figures and embodiment of the present invention.

Refer to FIG. 2. FIG. 2 shows a schematic view of an embodiment of a liquid crystal panel 60 according to the present invention. Liquid crystal panel 60 of the present invention comprises a pixel area 101 and a shorting bar area (not shown) disposed in peripheral area of pixel area 101.

According to the present embodiment, pixel area 101 of the liquid crystal panel is disposed with a plurality of data signal lines, a plurality of scan signal lines and common electrodes (all not shown). The plurality of data signal lines, scan signal lines and common electrodes all extend beyond the shorting bar area. As shown in FIG. 2, the plurality of data signal lines comprise a plurality of R signal lines, a plurality of G signal lines and a plurality of B signal lines. The plurality of scan signal lines further comprises a plurality of scan odd lines 201 and a plurality of scan even lines 202.

The shorting bar area further comprises a first area 102 and a second area 103. First area 102 is disposed with a plurality of first switches 111, a plurality of scan signal test points 100 and common electrode test point 119; wherein the plurality of scan test signal points 100 further comprises scan odd line test points 113 and scan even line test points 112. Each of the plurality of scan signal lines is connected to a corresponding scan signal test point 100 through a first switch 111.

Specifically, each of the plurality of scan odd lines 201 is connected to a corresponding scan odd test point 113 through a first switch 111, and each of the plurality of scan even lines 202 is connected to a corresponding scan even test point 112 through a first switch 111.

First area 102 further comprises: a control signal input point 114 for inputting control signal to first switches 111. First switch 111 is a thin film transistor (TFT), having a source terminal, a drain terminal and a gate terminal (all not shown). For scan odd line 201, first switch 111 has source terminal 2011 connected to scan odd line 201, drain terminal 2012 connected to scan odd line test point 113 and gate terminal 2013 connected to control signal input point 114 for inputting control signal to the first switches 111. For scan even line 202, first switch 111 has source terminal 2021 connected to scan odd line 202, drain terminal 2022 connected to scan even line test point 112 and gate terminal 2023 connected to control signal input point 114 for inputting control signal to the first switches 111. As seen, first switch 111 has source terminal connected to scan signal line, drain terminal connected to scan signal test point 100 and gate terminal connected to control signal input point 114 for inputting control signal to the first switches 111.

The present embodiment sends scan signal to scan odd line 201 and scan even line 202 through scan odd line test point 113 and scan even line test point 112, respectively, and controls status of conductive or turned off of first switch 111 through control signal input point 114 for inputting control signal to the first switches 111 to realize the control of scan signal.

With first switch 111 to isolate the same scan signal lines from forming a loop through test leads (as indicate by dash line 8 in FIG. 8), the same scan signal lines will not affect one another.

First switch 111 of the embodiment is not limited to the aforementioned TFT, and can be other three-terminal type of controlled switch, such as, triode.

First area 102 further comprises common electrode test point 119, connected to common electrode. Specifically, the common electrodes comprise common electrode 106 of color film glass substrate and common electrode 107 of array glass substrate. Common electrode 106 of color film glass substrate and common electrode 107 of array glass substrate are connected to common electrode test point 119 of the first area through conductive wire 108.

Refer to FIG. 2. Second area 103 is disposed with a plurality of data signal test points 200, and a plurality of unidirectional circuit 115. The input terminal of first unidirectional circuit 115 is connected to data signal test point 200, and output terminal is connected to R, G, B data signal lines; wherein data signal test point 200 comprises R signal line test point 116, G signal line test point 117 and B signal line test point 118.

Second area 103 is disposed with a plurality of first unidirectional circuit 115. Each of R signal lines is connected to R signal line test point 116 through first unidirectional circuit 115, and the input terminal of each unidirectional circuit 115 is connected to R signal line test point 116 and the output terminal is connected to R signal line. Similarly, each of G signal lines is connected to G signal line test point 117 through first unidirectional circuit 115, and the input terminal of each unidirectional circuit 115 is connected to G signal line test point 117 and the output terminal is connected to G signal line; each of B signal lines is connected to B signal line test point 118 through first unidirectional circuit 115, and the input terminal of each unidirectional circuit 115 is connected to B signal line test point 118 and the output terminal is connected to B signal line.

According to the present embodiment, unidirectional circuit 115 is a diode, with anode connected to data signal test point 200 and cathode is connected to data signal line. Specifically, each of R signal lines is connected to the cathode of a diode, and the anode of the diode is connected to R signal line test point 116; each of G signal lines is connected to the cathode of a diode, and the anode of the diode is connected to G signal line test point 117; and, each of B signal lines is connected to the cathode of a diode, and the anode of the diode is connected to B signal line test point 118.

With first unidirectional circuit 115 to isolate the same data signal lines from forming a loop through test leads (as indicate by dash line 9 in FIG. 8), the same data signal lines will not affect one another.

First unidirectional circuit 115 in the present embodiment is not limited to the aforementioned diode, and can be any other unidirectional circuitry structure.

For example, the present embodiment can be disposed with second switches (not shown) to replace aforementioned first unidirectional circuit 115. When second switches are disposed, second area 103 is also disposed with control signal input point (not shown) for inputting control signal to the second switches. Each of the second switches comprises a first terminal, a second terminal and a control terminal, with the first terminal connected to data signal test point, the second terminal connected to data signal line, and control terminal connected to control signal input point for inputting control signal to the second switches to control the second switch to stay conductive during product test, and turn off at other time.

When inputting R, G, B data signals, first unidirectional circuit 115 or the second switch is conductive; when stopping inputting R, G, B data signals, first unidirectional circuit 115 or the second switch is turned off.

Liquid crystal panel 60 in the present embodiment connects each scan odd line 201 and each scan even line 202 respectively to scan odd line test point 113 and scan even line test point 112 through a first switch 111, and first switch 111 controls the inputting of the scan signal so that each of scan signal lines will not interfere with one another. Liquid crystal panel 60 also connects each R signal line, each G signal line and each B signal line to corresponding R signal line test point 116, G signal line test point 117 and B signal line test point 118 respectively through a first unidirectional circuit or a second switch. The first unidirectional circuit or the second switch controls the inputting of data signal so that each of data signal lines will not interfere with one another. In this manner, liquid crystal panel 60 is spared with the cutting of test leads at shorting bar area during cell process and associated cutting facility. The test leads of the shorting bar area can be used in subsequent fabrication process for performing display on liquid crystal display, resulting in improving the display inspection accuracy and reducing cell process cost.

In addition, first switch 111, scan signal test point 100, common electrode test point 119 and control signal input point 114 for inputting control signal to first switch 111 disposed in first area 102 can also be disposed in second area 103. Also, data signal test point 200, first unidirectional circuit 115 or second switch, and the control signal input point for inputting control signal to second switch disposed in second area 103 can also be disposed in first area 102. No restriction is imposed here.

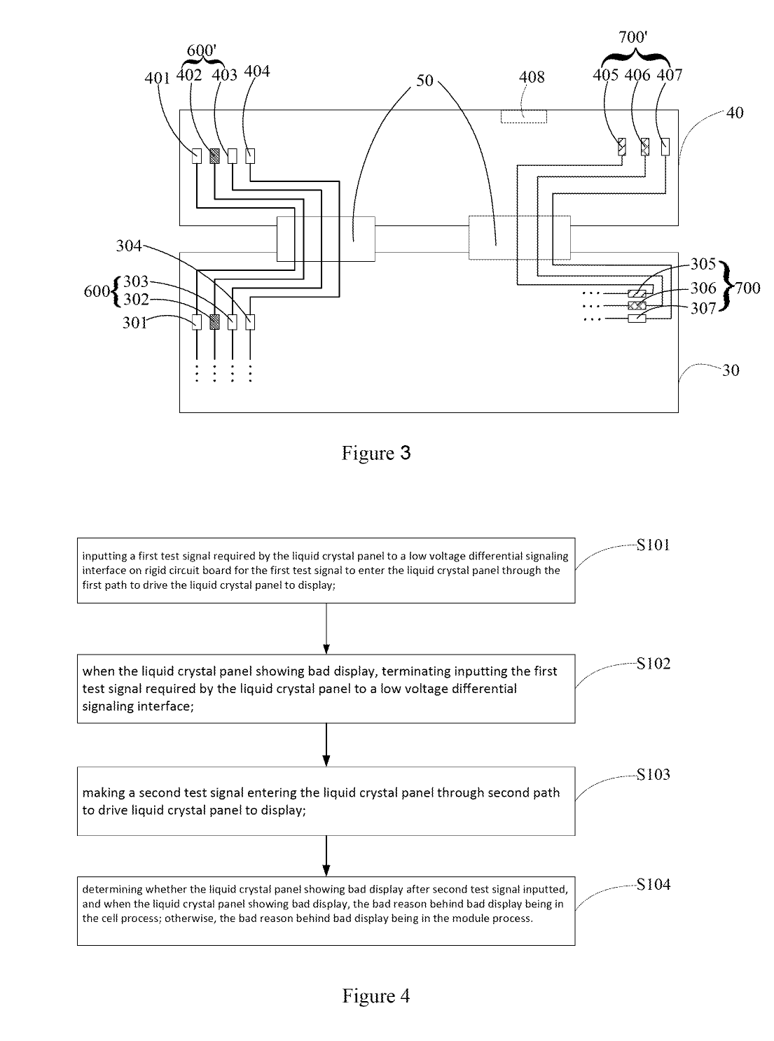

The present invention further provides an embodiment of a liquid crystal module, as shown in FIG. 3. FIG. 3 shows a schematic view of an embodiment of a liquid crystal module according to the present invention. In the present embodiment, a liquid crystal module comprises a liquid crystal panel 30, a rigid circuit board 40 and a flex circuit board 50. Liquid crystal panel 30 is liquid crystal panel 60 shown in the embodiment of FIG. 2. The detailed structure of liquid crystal panel 60 is described in the previous embodiment; therefore, for simplification, liquid crystal panel 30 in FIG. 3 is a simplified structure of liquid crystal panel 60 in FIG. 2.

Referring to FIG. 2 also, pixel area 101 of liquid crystal panel 30 is disposed with a plurality of data lines, a plurality of scan lines and common electrodes (not shown in FIG. 2). Shorting bar area further comprises a first area 102 and a second area 103. The plurality of data signal lines comprise a plurality of R signal lines, a plurality of G signal lines and a plurality of B signal lines. The plurality of scan signal lines further comprises a plurality of scan odd lines 201 and a plurality of scan even lines 202. The common electrodes further comprise common electrodes 106 of color film glass substrate and common electrodes 107 of array glass substrate.

Furthermore, first area 102 is disposed with a plurality of first switches 111, a plurality of first scan signal test points 600 (corresponding to scan line test points 100 in FIG. 2) and first common electrode test point 304 (corresponding to common electrode test point 119 in FIG. 2). Second area 103 is disposed with a plurality of first data signal test points 700 (corresponding to data signal test points 200 in FIG. 2), and a plurality of first unidirectional circuit 115. The plurality of first scan test signal points 600 further comprise first scan odd line test points 302 and first scan even line test points 303. The plurality of first data signal test points 700 comprise first R signal line test points 305, first G signal line test points 306 and first B signal line test points 307.

Each data signal line is connected to first data signal test point 700 through a first unidirectional circuit 115. The input terminal of first unidirectional circuit 115 is connected to first data signal test point 700 and the output terminal is connected to R, G, B data signal line. Each scan signal line is connected to first scan signal test point 600 through a first switch 111. The common electrode (not shown) is connected to first common electrode test point 304 through conductive wire 108.

In addition, first unidirectional circuit 115 of the present embodiment can also be a second switch (not shown). Each second switches comprises a first terminal, a second terminal and a control terminal, with the first terminal connected to data signal test point, the second terminal connected to data signal line, and control terminal connected to control signal input point for inputting control signal to the second switches to control the second switch to stay conductive during product test, and turn off at other time.

Refer to FIG. 3. Rigid circuit board 40 is disposed with a plurality of second scan signal test points 600′, each corresponding to each of a plurality of first scan signal test points 600 respectively. First scan signal test point 600 and second scan signal test point 600′ are electrically connected through flex circuit board 50. Specifically, rigid circuit board 40 is disposed with second scan odd line test point 402 corresponding to first scan odd line test point 302 (corresponding to scan odd line test point 113 in FIG. 2). First scan odd line test point 302 and second scan odd line test point 402 are electrically connected through flex circuit board 50. Rigid circuit board 40 is further disposed with second scan even line test point 403 corresponding to first scan even line test point 402 (corresponding to scan even line test point 112 in FIG. 2). First scan even line test point 303 and second scan even line test point 403 are electrically connected through flex circuit board 50.

Similarly, rigid circuit board 40 is disposed with a plurality of second data signal test points 700′, each corresponding to each of a plurality of first data signal test points 700 respectively. First data signal test point 700 and second data signal test point 700′ are electrically connected through flex circuit board 50. Specifically, rigid circuit board 40 is disposed with second R signal line test point 405 corresponding to first R signal line test point 305 (corresponding to R signal line test point 116 in FIG. 2). First R signal line test point 305 and second R signal line test point 405 are electrically connected through flex circuit board 50. Rigid circuit board 40 is disposed with second G signal line test point 406 corresponding to first G signal line test point 306 (corresponding to G signal line test point 117 in FIG. 2). First G signal line test point 306 and second G signal line test point 406 are electrically connected through flex circuit board 50; and rigid circuit board 40 is disposed with second B signal line test point 407 corresponding to first B signal line test point 307 (corresponding to B signal line test point 118 in FIG. 2). First B signal line test point 307 and second B signal line test point 407 are electrically connected through flex circuit board 50.

Rigid circuit board 40 is further disposed with a second common electrode test point 404, corresponding to first common electrode test point 304. First common electrode test point 304 and second common electrode test point 404 are connected through flex circuit board 50.

Furthermore, first area 102 of liquid crystal panel 30 further comprises: first control signal input point 301 (corresponding to control signal input point 114 in FIG. 2) for inputting control signal to first switches 301. Correspondingly, rigid circuit board 40 is disposed with a second control signal input point 401, corresponding to first control signal input point 301 for inputting control signal to the first switches. First control signal input point 301 and second control signal input point 401 are connected through flex circuit board 50.

According to the present embodiment, first switch 111 is a thin film transistor (TFT), having a source terminal, a drain terminal and a gate terminal. Also refer to FIG. 2. For scan odd line 201, first switch 111 has source terminal 2011 connected to scan odd line 201, drain terminal 2012 connected to first scan odd line test point 302 (corresponding to scan odd line test point 113 in FIG. 2) and gate terminal 2013 connected to first control signal input point 301 (corresponding to control signal input point 114 in FIG. 2) for inputting control signal to the first switches 111. For scan even line 202, first switch 111 has source terminal 2021 connected to scan odd line 202, drain terminal 2022 connected to first scan even line test point 303 (corresponding to even line test point 112 in FIG. 2) and gate terminal 2023 connected to first control signal input point 301 for inputting control signal to the first switches 111.

According to the present embodiment of the present invention, first unidirectional circuit 115 is a diode, with anode to connect with first data signal test point 700 (corresponding to data signal test point 200 in FIG. 2), and cathode to connect with data signal line.

When second area 103 of liquid crystal panel 30 is disposed with second switches (not shown), second area 103 is further disposed with third control signal input point (not shown) for inputting control signal to the second switches. Correspondingly, rigid circuit board 40 is disposed with a fourth control signal input point (not shown), corresponding to the third control signal input point for inputting control signal to the second switches. The third control signal input point and the fourth control signal input point are connected through flex circuit board 50.

According to the present embodiment, the second switch further comprises: a first terminal, a second terminal and a control terminal, with first terminal connected to first data signal test point 700, second terminal connected to data signal line and control terminal connected to third control signal input point for inputting control signal to the second switches to stay conductive only during product test and off otherwise.

Rigid circuit board 40 is further disposed with a low voltage differential signaling (LVDS) interface 408, for inputting drive signal of liquid crystal panel 30. Specifically, when performing display test on liquid crystal module, the drive signal required by liquid crystal panel 30 can be inputted through low voltage differential signaling interface 408 to drive liquid crystal panel 30 to display.

According to the present embodiment, the common electrodes comprise the common electrode (not shown) of color film glass substrate and common electrode (not shown) of array glass substrate. The common electrode of color film glass substrate and common electrode of array glass substrate are connected to first common electrode test point 304 (corresponding to common electrode test point 119 in FIG. 2) of the first area through conductive wire.

In summary, the liquid crystal module of the present embodiment electrically connects the data signal test point, scan signal test point and common electrode test point disposed on rigid circuit board 40 to the corresponding data signal test point, the scan signal test point and common electrode test point of liquid crystal panel 30 through the flex circuit board 50 so that the corresponding signal voltage can be imposed to the test points on rigid circuit board 40. The signal voltage can drive liquid crystal panel 30 to display through the test leads at the shorting bars area of the cell process to perform test on liquid crystal panel 30. On other hand, the drive signal required by liquid crystal panel 30 can also be inputted through low voltage differential signaling interface 408 to drive liquid crystal panel 30 to display. With two different inspection paths, when the liquid crystal panel shows bad display, the bad reason can be determined to be attributed to the cell process or the module process to improve the bad display (details will be described in the following method of determining reasons of bad display.) In other words, with the liquid crystal module of the present embodiment, the object of determining bad reasons to either cell process or module process when showing bad display can be realize, resulting in bad display improvement.

The present invention further provides a method of determining reason behind bad display of liquid crystal module, applicable to liquid crystal module described in the above embodiment. Refer to FIG. 4 and FIG. 3. FIG. 4 is a flowchart of an embodiment of the method of determining reason behind bad display of liquid crystal module according to the present invention, comprising the following steps:

S101: inputting a first test signal required by the liquid crystal panel to a low voltage differential signaling interface on rigid circuit board for the first test signal to enter the liquid crystal panel through the first path to drive the liquid crystal panel to display.

In the liquid crystal display device, the low voltage differential signaling interface circuit comprises two parts, the low voltage differential signaling interface circuit on the drive board side, and the low voltage differential signaling interface circuit on the liquid crystal panel side. The output interface circuit converts the parallel RGB data signal and control signal of 17 L voltage outputted by main control chip of drive board into low voltage serial differential signal, and then transmits the signal through the flax cable between the drive board and the liquid crystal panel to the low voltage differential signaling interface circuit on the liquid crystal panel side. The input interface circuit then converts the serial signal into parallel signal of TTL voltage, and transmits to timing control and row-column drive circuit of liquid crystal panel to drive the liquid crystal panel to display.

After completing liquid crystal module process, the liquid crystal panel 30 is inspected for display test. The first test signal required by liquid crystal panel 30 is inputted to low voltage differential signaling interface 408 on rigid circuit board 40 for the first test signal to enter liquid crystal panel 30 through the first path to drive liquid crystal panel 30 to display for inspection.

S102: when the liquid crystal panel showing bad display, terminating inputting the first test signal required by the liquid crystal panel to low voltage differential signaling interface.

The first test signal inputted to low voltage differential signaling interface 408 makes liquid crystal panel 30 light up for inspection the display. When the display is bad, it is necessary to determine the reason behind bad display. At this point, the first test signal inputted to low voltage differential signaling interface 408 is terminated.

S103: making a second test signal entering the liquid crystal panel through second path to drive liquid crystal panel to display.

The second path is formed by electrically connecting the second test point on (not shown) rigid circuit board 40, through flex circuit board 50 and the first test point (not shown) on liquid crystal panel 30.

Specifically, the second test point of rigid circuit board 40 comprises second scan signal test point 600′, second control signal input point 401, second common electrode test point 404 and second data signal test point 700′. The first test point of liquid crystal panel 30 comprises first scan signal test point 600, first control signal input point 301, first common electrode test point 304 and first data signal test point 700. According to the present embodiment, second scan signal test point 600′ comprises second scan odd line test point 402, second scan even line test point 403; second data signal test point 700′ comprises second R signal line test point 405, second G signal line test point 406 and second B signal line test point 407; first scan signal test point 600 comprises first scan odd line test point 302, first scan even line test point 303; first data signal test point 700 comprises first R signal line test point 305, first G signal line test point 306 and first B signal line test point 307. The second test point on rigid circuit board 40 is electrically connected to corresponding first test point on liquid crystal panel 30 through flax circuit board 50.

Because the test leads at the shorting bar area are not cut off during the cell process, the second test signal required by liquid crystal panel 30 can be inputted to test points 401-407 on rigid circuit board 40. The test signal enters liquid crystal panel 30 through test points 301-307 on liquid crystal panel 30 to drive liquid crystal panel 30 to light up for display inspection.

S104: determining whether the liquid crystal panel showing bad display after second test signal inputted, and when the liquid crystal panel showing bad display, the bad reason behind bad display of liquid crystal panel being determined to be in the cell process; otherwise, the bad reason behind bad display of liquid crystal panel being determined to be in the module process.

When executing step S101, the test signal is supplied to liquid crystal panel 30 through the low voltage differential signaling interface circuit of the module process to drive liquid crystal panel 30. When liquid crystal panel 30 shows bad display, the reason behind bad display cannot be attributed to cell process or module process of liquid crystal fabrication process because the test signal from the low voltage differential signaling interface circuit passes through both circuits and structure fabricated during cell process and module process. Any problem caused by cell process and module process can result in the bad display. To determine the reason behind bad display, the second signal required by liquid crystal panel 30 inputted through the second path passes the test leads of shorting bar area of the cell process to drive the liquid crystal panel to display to prevent the test signal from passing the circuits and structure fabricated during module process. When the bad display shows up at this point, the reason behind bad display can be attributed to cell process and possibly module process, too. When the display is good, the cell process does not cause any defect and the defect should be from the module process.

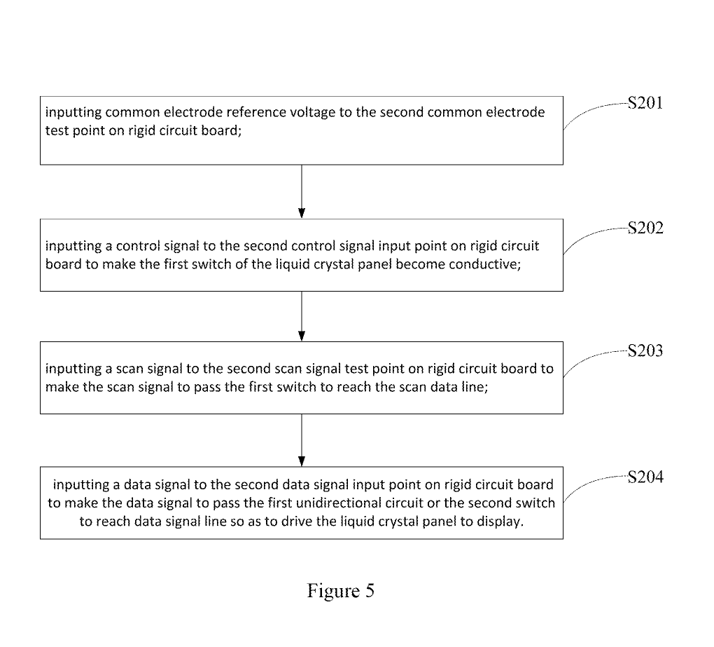

Refer to FIG. 5, FIG. 3 and FIG. 4. FIG. 5 shows a flowchart of an embodiment of the step of making second test signal enter liquid crystal panel through the second path, comprising the steps of:

S201: inputting common electrode reference voltage to the second common electrode test point on rigid circuit board.

A common electrode reference voltage is inputted to second common electrode test point 404 on rigid circuit board 40. Because second common electrode test point 404 is electrically connected to first common electrode test point 304 on liquid crystal panel 30 through flex circuit board 50, the common electrode reference voltage is supplied to common electrode of liquid crystal panel 30.

S202: inputting a control signal to the second control signal input point on rigid circuit board to make the first switch of the liquid crystal panel become conductive.

The control signal can be high voltage. By inputting a high voltage to second control signal input point 401, the first switch of liquid crystal panel 30 become conductive.

S203: inputting a scan signal to the second scan signal test point on rigid circuit board to make the scan signal to pass the first switch to reach the scan data line.

Specifically, according to the requirement of inspection, VgH and VgL scan signals are inputted to second scan odd line test point 402 and second scan even line test point 403 respectively, to make first scan odd line test point 302 and first scan even line test point 303 also show VgH and VgL scan signals respectively. The scan signals are supplied to scan data line through the first switch of liquid crystal panel 30.

S204: inputting a data signal to the second data signal input point on rigid circuit board to make the data signal to pass the first unidirectional circuit or the second switch to reach data signal line so as to drive the liquid crystal panel to display.

Specifically, inputting R, G, B display signals to second R signal test point 405, second G signal test point 406, second B signal test point 407 on rigid circuit board 40 respectively to make R, G, B display signals also appearing at first R signal test point 305, first G signal test point 306, first B signal test point 307 on liquid crystal panel 30. The display signals are supplied to data signal line through first unidirectional circuit or second switch to light up the panel.

In summary, after executing step S101, when liquid crystal panel 30 shows bad display, the reason behind bad display cannot be attributed to cell process or module process of liquid crystal fabrication process because the test signal from the low voltage differential signaling interface circuit passes through both circuits and structure fabricated during cell process and module process. Any problem caused by cell process and module process can result in the bad display. To determine the reason behind bad display, the second signal required by liquid crystal panel 30 inputted through the second test point passes the test leads of shorting bar area of the cell process to drive the liquid crystal panel to display to prevent the test signal from passing the circuits and structure fabricated during module process. When the display is good, the cell process does not cause any defect and the defect should be from the module process. When the bad display also shows up at this point, the reason behind bad display can be attributed to cell process and possibly module process, too. In this manner, the bad display in step S101 can be determined to attribute to cell process or module process to assist in improving the bad display.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A liquid crystal panel, which comprises: a pixel area and a shorting bar area for testing, disposed in peripheral area of the pixel area;
the pixel area of the liquid crystal panel being disposed with a plurality of data signal lines, a plurality of scan signal lines and common electrodes; the shorting bar area further comprising a first area and a second area;
the first area being disposed with a plurality of first switches, a plurality of scan signal test points and common electrode test point; and the second area being disposed with a plurality of data signal test points, and a plurality of unidirectional circuit or second switches;
each of the data signal lines being connected with the data signal test point through the first unidirectional circuit or second switch; the first unidirectional circuit is a diode, with anode as input terminal to connect with the data signal test point, and cathode as output terminal to connect with the data signal line;
each of the scan signal lines being connected with the scan signal test point through a first switch;
the common electrodes comprising the common electrode of color film glass substrate and common electrode of array glass substrate; the common electrode of color film glass substrate and common electrode of array glass substrate being connected to the common electrode test point of the first area through conductive wire.

2. The liquid crystal panel as claimed in claim 1, wherein:
the first area is further disposed with control signal input point for inputting control signal to the first switches;
the first switch is a thin film transistor (TFT) having a source terminal, a drain terminal and a gate terminal, with source terminal connected to scan signal line, drain terminal connected to scan signal test point and gate terminal connected to control signal input point for inputting control signal to the first switches.

3. The liquid crystal panel as claimed in claim 1, wherein:
the second area is disposed further with control signal input point for inputting control signal to the second switches;
the second switch comprises a first terminal, a second terminal and a control terminal, with first terminal connected to data signal test point, second terminal connected to data signal line and control terminal connected to control signal input point for inputting control signal to the second switches to stay conductive only during product test and off at other time.

4. A liquid crystal module, which comprises:
a liquid crystal panel, a rigid circuit board and a flex circuit board; the liquid crystal panel further comprising a pixel area and a shorting bar area for testing, disposed in peripheral area of the pixel area;
the pixel area of the liquid crystal panel being disposed with a plurality of data signal lines, a plurality of scan signal lines and common electrodes; the shorting bar area further comprising a first area and a second area;
the first area being disposed with a first switches, a plurality of first scan signal test points and a first common electrode test point; and the second area being disposed with a plurality of first data signal test points, and a plurality of unidirectional circuit or second switches;
each of the data signal lines being connected with first data signal test point through a first unidirectional circuit or second switch;
input terminal of the first unidirectional circuit being connected to first data signal test point, and output terminal of the first unidirectional circuit being connected to data signal line;
each of the scan signal lines is connected with first scan signal test point through a first switch;
the common electrodes being connected to common the first electrode test point of the first area through conductive wire;
the rigid circuit board being disposed with a plurality of second scan signal test points, corresponding to each of a plurality of first scan signal test points respectively; the first data signal test point and the second data signal test point being connected through the flex circuit board;
the rigid circuit board being disposed with a second common electrode test point, corresponding to the first common electrode test point; the first common electrode test point and the second common electrode test point being connected through the flex circuit board;
the rigid circuit board being further disposed with a low voltage differential signaling interface, for inputting drive signal of liquid crystal panel.

5. The liquid crystal module as claimed in claim 4, wherein
the first area further comprises first control signal input point for inputting control signal to the first switches;
the rigid circuit board is disposed with a second control signal input point, corresponding to the first control signal input point for inputting control signal to the first switches; the first control signal input point and the second control signal input point are connected through flex circuit board.

6. The liquid crystal module as claimed in claim 5, wherein
the first switch is a thin film transistor (TFT), having a source terminal, a drain terminal and a gate terminal, with source terminal connected to scan signal line, drain terminal connected to first scan signal test point and gate terminal connected to first control signal input point for inputting control signal to the first switches.

7. The liquid crystal module as claimed in claim 4, wherein
the first unidirectional circuit is a diode, with anode to connect with first data signal test point, and cathode to connect with data signal line.

8. The liquid crystal module as claimed in claim 4, wherein
the second area is further disposed with third control signal input point for inputting control signal to the second switches;
the rigid circuit board is disposed with a fourth control signal input point, corresponding to the third control signal input point for inputting control signal to the second switches; the third control signal input point and the fourth control signal input point are connected through flex circuit board.

9. The liquid crystal module as claimed in claim 8, wherein
the second switch further comprises: a first terminal, a second terminal and a control terminal, with first terminal connected to first data signal test point, second terminal connected to data signal line and control terminal connected to third control signal input point for inputting control signal to the second switches to stay conductive during product test and turned off at other time.

10. The liquid crystal module as claimed in claim 4, wherein
the common electrodes comprise common electrode of color film glass substrate and common electrode of array glass substrate; the common electrode of color film glass substrate and common electrode of array glass substrate are connected to the first common electrode test point of the first area through conductive wire.

11. A method of determining reason behind bad display for liquid crystal module, applicable to liquid crystal module as claimed in claim 4, the method comprises:
inputting a first test signal required by liquid crystal panel to a low voltage differential signaling interface on rigid circuit board for the first test signal to enter the liquid crystal panel through a first path to drive the liquid crystal panel to display;
when the liquid crystal panel showing bad display, terminating inputting the first test signal required by the liquid crystal panel to a low voltage differential signaling interface;
after terminating inputting the first test signal, making a second test signal entering the liquid crystal panel through a second path to drive liquid crystal panel to display; the second path being formed by electrically connecting second test point on rigid circuit board, through flex circuit board and the first test point on the liquid crystal panel; the second test point further comprising: a second scan signal test point, a second control signal input point, a second common electrode test point and a second data signal test point; the first test point further comprising: a first scan signal test point, a first control signal input point, a first common electrode test point and a first data signal test point;
determining whether the liquid crystal panel showing bad display after second test signal inputted, and when the liquid crystal panel showing bad display, the bad reason behind bad display of liquid crystal panel being determined to be in the cell process; otherwise, the bad reason behind bad display of liquid crystal panel being determined to be in the module process.

12. The method as claimed in claim 4, wherein the step of making a second test signal entering the liquid crystal panel through a second path to drive liquid crystal panel to display further comprises:
inputting a common electrode reference voltage to the second common electrode test point on rigid circuit board;
after inputting common electrode reference voltage, inputting a control signal to the second control signal input point on rigid circuit board to make the first switch of the liquid crystal panel become conductive, wherein the first switch is a thin film transistor (TFT), having a source terminal, a drain terminal and a gate terminal, with source terminal connected to scan signal line, drain terminal connected to first scan signal test point and gate terminal connected to first control signal input point for inputting control signal to the first switches;
after inputting control signal, inputting a scan signal to the second scan signal test point on rigid circuit board to make the scan signal to pass the first switch to reach the scan data line;
after inputting the scan signal, inputting a data signal to the second data signal input point on rigid circuit board to make the data signal to pass the first unidirectional circuit or the second switch to reach data signal line so as to drive the liquid crystal panel to display; the first unidirectional circuit being a diode, with anode connected to the first data signal test point and cathode connected to data signal line; the second switch having a first terminal, a second terminal and a control terminal, with the first terminal connected to the first data signal test point, the second terminal connected to the data signal line and the control terminal connected to the second control signal input point to the second switch.

13. The method as claimed in claim 12, wherein the step of inputting control signal to the second control single input point on rigid circuit board further comprises:
inputting a high voltage to the second control single input point on rigid circuit board so as to make the first switch of the liquid crystal panel to become conductive.
